(19) United States
(12) Patent Application Publication
(10) Pub. No.: US 2026/0182272 A1
(43) Pub. Date: Jun. 25, 2026

(54) METHOD FOR MANUFACTURING AN ARRAY INCLUDING AT LEAST TWO MEMORY CELLS AND ARRAY THEREFOR

(71) Applicant: COMMISSARIAT À L’ENERGIE ATOMIQUE ET AUX ENERGIES ALTERNATIVES, PARIS (FR)

(72) Inventors: Julien BORREL, GRENOBLE CEDEX 9 (FR); Yann BEILLIARD, GRENOBLE CEDEX 9 (FR); Michele MARTEMUCCI, GRENOBLE CEDEX 9 (FR); Laurent GRENOUILLET, GRENOBLE CEDEX 9 (FR); Tifenn HIRTZLIN, GRENOBLE CEDEX 9 (FR); François RUMMENS, GRENOBLE CEDEX 9 (FR); Elisa VIANELLO, GRENOBLE CEDEX 9 (FR)

(21) Appl. No.: 19/427,110

(22) Filed: Dec. 19, 2025

(30) Foreign Application Priority Data
Dec. 19, 2024 (FR) FR2414621

(51) Int. Cl. H10P 30/40; H10B 53/30; H10B 63/00

(52) U.S. Cl. CPC H10P 30/40; H10B 53/30; H10B 63/22

(57) ABSTRACT

A method for manufacturing an array of memory cells including at least two memory cells, the method including providing a substrate; forming at least a first and a second cavity in the substrate; the first and second cavities being oriented such that the second cavity undergoes rotation by a non-zero angle about an axis normal to the substrate relative to said first cavity, the method including the following procedures implemented in each of the cavities: depositing a first conductive layer; depositing an active layer; depositing a second conductive layer; the method further including at least one ion implantation procedure such that the areas of the active layers exposed to implantation in the first and second cavities, which are oriented differently, are different.

### CROSS-REFERENCE TO RELATED APPLICATIONS

This application claims priority to French Patent Application No. FR 2414621, filed Dec. 19, 2024, the entire content of which is incorporated herein by reference in its entirety.

### FIELD

The present invention generally relates to the field of microelectronics. It more particularly relates to the field of non-volatile memories.

In particular, the invention relates to a method for manufacturing an array of memory cells (or bitcells), especially based on ferroelectric materials. It also relates to an array of memory cells.

### BACKGROUND

For applications that require information to be stored even when electric power is turned off, non-volatile EEPROM or FLASH memories are conventionally used.

Other emerging types of non-volatile memory that are based on active materials such as ferroelectric materials (FeRAM memories) or materials such as oxides (OxRAM memories) are a promising alternative to FLASH or EEPROM memory.

The main advantage of ferroelectric FeRAM (Ferroelectric Random Access Memory) memories is that they are non-volatile, i.e. they retain stored information even when the power is turned off. They also have the advantages of consuming less energy and having shorter write and reading times relative to other types of emerging or mature non-volatile memories such as FLASH memories.

FeRAM ferroelectric memories generally take the form of a stack in which a layer of ferroelectric material is positioned between two metallic electrodes. Ferroelectric memories are capacitive memories with two remanent polarisation states, +Pr and −Pr. These memories operate based on the properties of the ferroelectric material to be placed between two metallic electrodes.

More particularly, as regards the operation of FeRAM ferroelectric memories, applying a potential difference between the two electrodes creates an electric field with a value greater than a positive coercive field +Ec, the ferroelectric memory is placed in a high remanent polarisation state +Pr and by applying a potential difference creating an electric field with a value lower than the negative coercive field −Ec, the ferroelectric memory is placed in a low remanent polarisation state −Pr. Thus, during writing to the memory, a current peak is measured during the reversal of the ferroelectric domains, which occurs when the applied electric field is greater than the coercive field.

The high remanent polarisation state +Pr then corresponds to the binary logic state ‘0’and the low remanent polarisation state −Pr to the binary logic state ‘1’, which allows information to be stored.

Additionally, when the application of the potential difference between the two metallic electrodes is stopped, the remanent polarisation state remains: this explains the non-volatile nature of ferroelectric memories.

For reading, it is assumed that the memory is in a given state and a voltage is applied. This voltage is, for example, positive, greater than the voltage creating an electric field with a value greater than the positive coercive field +Ec. Thus, if the memory was already in the high remanent polarisation state +Pr, this polarisation state remains unchanged and no current peak is observed (or a very small current peak may be observed). Conversely, if the memory was in the low remanent polarisation state −Pr, a much larger current peak is observed. The consequence of this reading operation is that it is destructive to the polarisation state. It is therefore necessary to rewrite the initial polarisation state after reading if this state has been modified.

FeRAM type ferroelectric memories can, for example, be integrated into memory arrays with which it is possible to perform logic operations. In this case, each FeRAM memory is generally connected in series with a transistor T so as to form a 1T-1C type memory cell (for one transistor and one ferroelectric capacitive memory C). For illustrative purposes only, FIG. 1 represents part of an array compound of two types of horizontal lines, Word Lines (WL) and Source Lines (SL), and vertical lines, called Bit Lines (BL). Herein, two memory cells are represented, each including a ferroelectric memory (C0 and C1) and a transistor (T0 and T1) in series. The WL lines are connected to the gates of the transistors in order to activate the same. The bit lines BL are connected to the sources or drains of the transistors, and the source lines are connected to the electrode of the ferroelectric memory that is not connected to the transistor in series. FIG. 1 also represents a simplified representation of the equivalent dielectric capacitance C_{BL} of the bit line BL. Reading a cell is performed by applying a voltage pulse greater than the voltage creating an electric field with a value greater than the coercive field on the SL line. It is possible to read both cells T1-C1 and T2-C2 at the same time (parallel reading). Reading is performed, for example, by virtue of a voltage sense amplifier (SA) present at the end of the BL line. The SA has two inputs and allows an external reference voltage V_{ref} to be compared with the voltage V_{BL}. Thus, as a function of the measured voltage V_{BL} and the voltage reference V_{ref} selected, it is possible to perform logic operations, for example, “AND” (logical “and”) or “OR” (logical “or”) operations. The voltage V_{BL} approximately corresponds to the sum of the voltages across the two ferroelectric capacitive memories C0 and C1. It will be noted that other memory plane configurations are also contemplatable, wherein, for example, the SL is parallel to the BL or the accumulation takes place at the source line SL and not at the bit line BL. FIG. 2 shows the value of the voltage V_{BL} as a function of the logic states “0” or “1” of the ferroelectric memories C0 and C1: V_{BL} is a voltage that will depend on capacitive sharing between the capacitors of memories C0 and C1 and capacitor C_{BL}. It can be considered that, during the operation of reading the state of a ferroelectric memory, the state “0” only includes the dielectric charge of the capacitance, while the state “1” is the sum of this dielectric charge and the ferroelectric contribution (obtained during the prior programming of the memory), thus causing an increase in the voltage across the memory. In FIG. 2, four values of V_{BL} corresponding to the logic combinations “00”, “01”, “10” and “11” of the two ferroelectric memories C0 and C1 are thus observed. By selecting a relevant value for the reference voltage V_{ref}, it is possible to perform a logic operation on the logic states of memories C0 and C1: the voltage V_{ref,AND} enables an “and” operation to be performed, while the v_{ref,OR} enables an “OR” operation to be performed: this operation is performed by comparing the voltage V_{BL} with the reference voltage. The table represented in FIG. 3 shows that both operations are actually performed as a function of the selected reference voltage (A representing the logic state of memory C0 and B representing the logic state of memory C1). However, FIG. 2 also shows that it is not possible to distinguish between the two states “01” and “10”, which substantially correspond to a same voltage V_{BL}. In other words, the contribution to the voltage V_{BL} is the same for both memory points. This result is quite understandable insofar as the ferroelectric memories C0 and C1 are identical in terms of both the materials used and their geometry. Further, in the state “1”, it can be shown that the voltage value of each ferroelectric memory depends directly on the surface area S of the active ferroelectric layer forming the memory.

One solution that would make it possible achieve to discriminate between two memory points with different bit weights (i.e. so that their voltage contribution is different) could be to design ferroelectric memories of different sizes. FIG. 4 shows an array of three planar ferroelectric memories, each memory being made up of a stack of a lower TiN electrode, a ferroelectric layer of Hf_{0.5}Zr_{0.5}O₂ (called HZO) and an upper TiN layer. The three memories are different from each other in that the surface area of the active ferroelectric layer is different for each memory, ranging from a surface area S for the first memory to a surface area S/2 for the second and a surface area S/4 for the third.

The drawback of such a solution based on planar layers is that it results in a large area footprint.

To reduce this footprint, one solution can consist in using a three-dimensional (3D) approach. In other words, as illustrated in FIG. 5, the ferroelectric memories are now made in 3D cavities so as to reduce the base footprint and have a ferroelectric active layer surface that is distributed both at the bottom of the cavity and on the sides. FIG. 5 shows three ferroelectric memories, M1, M2 and M3, each made in the form of a cavity including, respectively, a bottom TiN electrode, a ferroelectric HZO layer and an upper TiN layer. The three memories each have a different aspect ratio defined by the ratio hᵢ/lᵢ, where hᵢ is the height of memory Mᵢ relative to the base plane and Iᵢ is the width of memory Mi (or the diameter in the case of a circular lower surface). Such a solution enables the footprint to be reduced while retaining the capacitance value by using the lateral surfaces of the cavities. However, there are also some drawbacks, especially relating to the manufacturing method: cavities with different widths do not etch at a same rate; filling the cavities with a conductive material is more complex than depositing it onto a planar surface.

It may additionally be useful to have OxRAM and FeRAM memories co-integrated on a same array due to the limitations of either reading for FeRAM or writing for OxRAM.

OxRAM memories, for oxide-based RAM, are non-volatile resistive memories. These memories can have at least two resistive states, corresponding to a High Resistance State (HRS) and a Low Resistance state (LRS), under application of a voltage. OxRAM memories have an M-I-M (Metal-Insulator-Metal) structure comprising an active material with variable electrical resistance, generally a transition metal oxide (e.g. WO₃, HfO₂, Ta₂O₅, TiO₂, etc.), disposed between two metallic electrodes. One of the two electrodes often includes a metallic layer, for example of Ti, for creating oxygen vacancies in the active layer, for example based on hafnium dioxide, in the OxRAM when this conductive layer is in contact with the active layer of the OxRAM. The transition from the “HRS” state to the “LRS” state is indeed governed by the formation and breaking of a conductive filament between the two electrodes. This conductive filament is created by virtue of the presence of oxygen vacancies in the active layer of the memory. By modifying the potentials applied to the electrodes, it is possible to modify distribution of the filament and thus modify the electrical conduction between the two electrodes. In the active layer, the electrically conductive filament is either broken or reformed to vary the resistance level of the memory cell during write and reset cycles of that cell (SET operations, when the filament is reformed, resulting in the LRS state, and RESET operations, resulting in the HRS state, when the filament is broken again by applying a SET voltage, V_{SET} or RESET voltage, V_{RESET} across the electrodes). The use of a filamentary memory includes a so-called “forming” step, during which the filament is formed for the first time in the active layer, which initially is free of filament. The active layer is indeed initially completely electrically insulating. During the initial “forming” step, an electrically conductive filament is formed in the active layer by making a kind of controlled breakdown of this layer. The filament thus formed then extends from one side to the other through the active layer, electrically connecting the bottom electrode and the top electrode. To perform this forming step, an electrical voltage can for example be applied between the bottom electrode and the top electrode of the memory cell in question, and then gradually increased to a threshold voltage, referred to as the forming voltage V_{forming}, above which breakdown of the active layer is achieved. After this forming step, the memory cell is ready for use. The conductive filament can then be broken, and then reformed, broken again, and so on, at a voltage value lower than the forming voltage V_{forming}.

Main advantages of OxRAM memories are that they are non-volatile, i.e. they retain the stored information even when the voltage is cut off, they have low write and reading times relative to other types of non-volatile memories such as FLASH memories, can be integrated into chips on a massive scale due to their small size and the thinness of the active layers, and allow for back-end integration compatible with CMOS technology.

The co-integration of OxRAM and FeRAM memories on a same chip relies on relatively complex manufacturing methods that can be improved.

### SUMMARY

The present invention aims to provide a method for manufacturing an array including three-dimensional memory cells with different active surfaces, said method being simpler to implement than the solutions previously set forth.

The invention especially relates to a method for manufacturing an array of memory cells including at least two memory cells, the method comprising the steps of:
providing a substrate;
forming at least a first and a second cavity in the substrate;
   the first and second cavities being oriented such that the second cavity undergoes a rotation of a non-zero angle about an axis normal to the substrate relative to said first cavity, said method including the following steps implemented in each of the cavities:
depositing a first conductive layer;
depositing an active layer;
depositing a second conductive layer;
   the method further including at least one ion implantation step such that the areas of the active layers exposed to implantation of the first and second cavities, oriented differently, are different.

By active layer, it is meant a memory layer, i.e. a layer made of a material capable of reversibly and switching in a non-volatile manner between two physical states that vary a specific property (conductance, capacitance, etc.).

By virtue of the invention, ion implantation is used to amorphise part of the active layer of each memory cell, causing that part of the active layer to lose its properties, for example the ferroelectric nature of the active layer. By doing so, the developed active surface is reduced. With at least one constant and identical implantation step for each cavity, the invention further makes it possible to obtain different non-amorphised surfaces. By rotating the cavities relative to each other, the implantation will act on different surfaces due to the different orientation of the cavities to create different amorphisations and therefore different developed active surfaces. Thus, in the case of an array including ferroelectric memory cells, the active layer of each FeRAM-type memory is a ferroelectric layer crystallised in an orthorhombic state or an antiferroelectric layer crystallised in a tetragonal state: at least one implantation will amorphise some crystallised zones of each of the layers, by removing their ferroelectric or antiferroelectric properties, but the amorphisation will not occur in the same places on the surface for the two active layers. This results in two memory cells with different active surfaces but with identical dimensions and materials.

In addition to the characteristics discussed in the preceding paragraphs, the method according to the invention may have one or more of the following additional characteristics, considered individually or according to any technically possible combination:

Each of the first and second conductive layers are metallic layers.

Each of said first and second cavities:
has the same geometry and same dimensions;
comprises a side wall and a bottom wall, said bottom wall having a plurality of sides, at least two of which have different lengths.

Thus, the method according to the invention uses at least two cavities that are identical in terms of geometry and materials, but these two cavities are rotated relative to each other. Insofar as the base of each cavity has at least two sides of different lengths (i.e. the base of the cavity is neither square nor circular, for example), the areas of each active layer as seen by the implantation are different even with identical cells. According to this embodiment, the angle of rotation of the second cavity relative to the first is not equal to 180°in order to avoid the same areas being exposed.

The bottom wall has a shape with an even number of sides formed by a plurality of sides opposite to each other with the same length, at least two pairs of sides having different lengths.

The memory cells are at least partly ferroelectric FeRAM memories, the active layer being a ferroelectric or antiferroelectric layer.

The memory cells are at least partly OxRAM memories, with the active layer being a metal oxide-based layer.

The array of memory cells includes at least one FeRAM memory and at least one OxRAM memory. According to the latter embodiment, a co-integration of FeRAM and OxRAM memory cells is therefore achieved.

The active layer material is hafnium dioxide HfO₂ doped with Si or an alloy Hfₓ Zr₁₋ₓO₂, with 0<x<1, or aluminium and scandium nitride AlScN. It will be noted that the active layer material, such as hafnium dioxide HfO₂, can also be doped with one of the following elements: N, Gd, Y, Sc, Ge with a doping percentage between 0 and 10% and in an embodiment between 0.5 and 3%.

The implantation dose is between 1.10¹⁴ cm⁻² and 1.10¹⁷cm⁻² and the acceleration voltage is between 0.2 kV and 10 kV.

The implantation with a view to amorphising the active layer is performed using one of the following atoms: Ge, As, Sb, In, P, Si, Ga, C or B.

The method according to the invention includes two ion implantation steps in two different directions to target different surfaces of each of the active layers.

The first implantation is performed with a rotation angle of the substrate in the plane of the substrate of 0°, and the second implantation is performed with a rotation angle of the substrate in the plane of the substrate of 180°. In this case, the conditions for the second implantation are in an embodiment identical to those for the first implantation, with only the rotation angle of the substrate having been modified.

The implantation is performed with a tilt angle between the ion beam and the normal to the substrate surface strictly less than 90°and in an embodiment between 10 and 40°.

The first and second cavities are oriented such that the second cavity undergoes a rotation of 90°about an axis normal to the substrate relative to said first cavity.

According to a first embodiment, implantation can be made through the second conductive layer using an acceleration voltage high enough to pass therethrough.

According to a second embodiment, the method according to the invention includes the steps of:
removing the second conductive layer, the implantation being directly performed in the active layer after removing the second conductive layer;
depositing a new conductive layer onto the active layer after implantation.

The invention also relates to an array including at least two memory cells comprising:
at least a first and a second cavity in a substrate, the first and second cavities being oriented such that the second cavity has a rotation of a non-zero angle about an axis normal to the substrate relative to said first cavity, each of the first and second cavities including:
   a first conductive layer forming a bottom electrode;
   an active layer;
   a second conductive layer forming a top electrode;
      the active layers of the first and second cavities having different implanted areas.

### BRIEF DESCRIPTION OF THE FIGURES

Further characteristics and benefits of the invention will become apparent from the description thereof given below, by way indicating and in no way limiting purposes, with reference to the appended figures, including:

FIG. 1 illustrates part of a ferroelectric memory array in a 1T-1C configuration,

FIG. 2 represents the bit line voltage values as a function of the logic states of the memories of FIG. 1,

FIG. 3 is a table showing the results of two logic operations, “and” and “or”, performed using the array of FIG. 1,

FIG. 4 shows a schematic cross-section view of planar ferroelectric capacitors with different HZO-based active surfaces,

FIG. 5 illustrates a schematic cross-section view of three-dimensional ferroelectric capacitors with different HZO-based active surfaces,

FIG. 6 shows a top view and a top view of an implantation simulation illustrating the method according to the invention, which will be detailed with reference to FIGS. 7 to 18.

FIG. 7, FIG. 8, FIG. 9, FIG. 10, FIG. 11 and FIG. 12 illustrate the different steps of the method according to one embodiment of the invention,

FIG. 13, FIG. 14, FIG. 15 and FIG. 16 illustrate the different steps of the method according to one second embodiment of the invention.

FIG. 17 illustrates an alternative of the method according to the invention,

FIG. 18 illustrates an alternative of the method according to the invention.

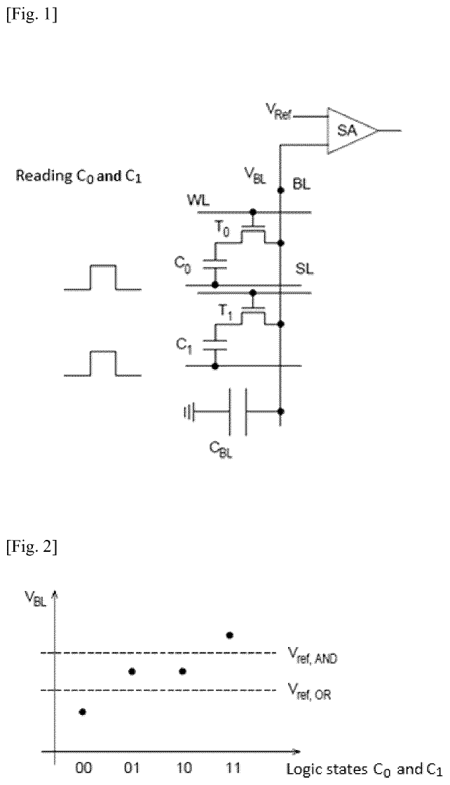

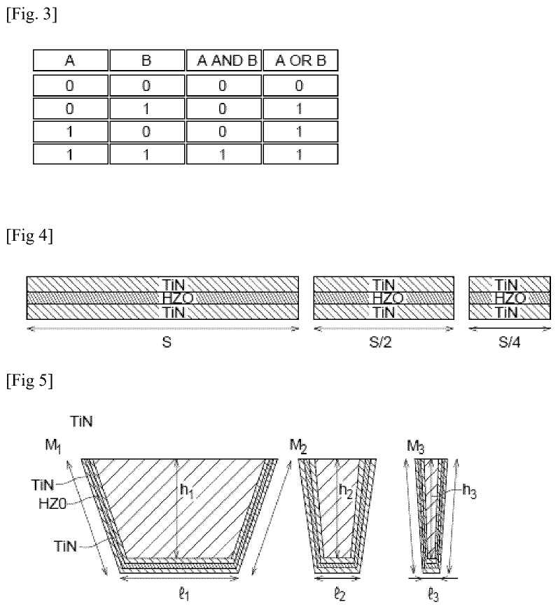

For clarity, identical or similar elements are identified by identical reference signs in all the figures.

### DETAILED DESCRIPTION

The present invention aims to improve the manufacture of memory cells, especially ferroelectric memory cells.

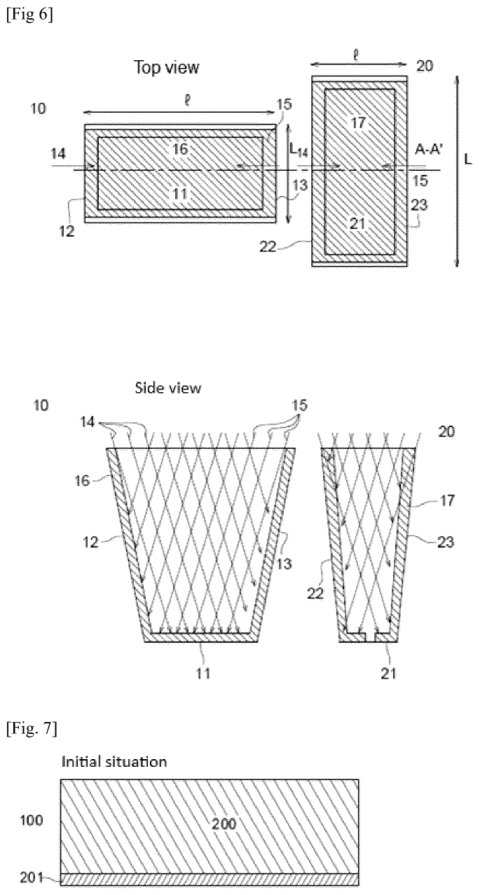

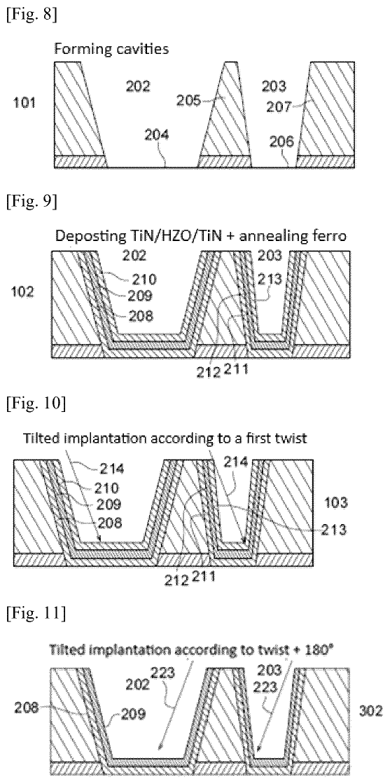

FIG. 6 shows a top view and a side view of an implantation simulation illustrating the method according to the invention, which will be detailed with reference to FIGS. 7 to 18.

FIG. 6 shows two cavities 10 and 20 in top view and side view.

Each of the cavities 10 and 20 includes:
a bottom wall 11 and 21
two side walls, respectively 12 and 13 for cavity 10 (references 12 and 13 representing each side of the side wall of cavity 10) and 22 and 23 for cavity 20 (references 22 and 23 representing each side of the side wall of cavity 20).

Each of the cavities 10 and 20 is hollow and initially beneficially made of the same material, for example ferroelectric (i.e. the side walls and the bottom wall). For the record, to achieve ferroelectric properties, the active material is most often a material crystallised in an orthorhombic or tetragonal phase.

For illustrative purposes only, the side walls of each of the cavities are tilted at a same non-zero angle relative to the normal to the base wall, it being understood that the invention also applies to a non-tilted wall (i.e. normal to the plane of the substrate).

The cavities 10 and 20 are in an embodiment, but non-limited to, strictly identical in terms of geometry, and the active material of which they are initially made up is the same. The bottom walls 11 and 21 herein, for illustrative purposes only, have a rectangular shape with a width L and a length l. The width L is different from the length l. It will be seen later that the bottom walls can have a more complex shape.

As illustrated in FIG. 6, the two identically shaped cavities 10 and 20 are rotated relative to each other by a non-zero angle, here 90°.

The invention is based on performing at least one ion implantation step in a given direction on both the active layer forming cavity 10 and the active layer forming the cavity 20.

In this case, two successive ion implantations 14 and 15 are performed on each of the active layers of cavities 10 and 20.

For the record, two angles can be defined that are necessary for parameterizing the ion beam relative to the crystal lattice. These angles are the tilt angle T and the twist angle R. R. The tilt angle T is the angle between the ion beam and the normal to the surface of the target substrate, herein the plane of the base wall. The twist angle R is the angle between the projection of the incident beam in the plane of the substrate and the axis of the notch of the substrate (represented herein by line AA′).

The first ion implantation 14 is performed with a twist angle equal to 0 and a non-zero tilt angle (the tilt angle may be zero in this case).

The second ion implantation 15 is performed with the same tilt angle as the first ion implantation 14 and a twist angle of 180°.

By operating in this way, it is noticed that each of the ion implantations will reach different surface zones of cavities 10 and 20. These surface zones are represented by hatched zones 16 (for cavity 10) and 17 (for cavity 20).

The implantation conditions will be described in more detail with reference to the figures describing the entire method.

Ion implantations 14 and 15 will amorphise (i.e. cause the loss of crystallographic, and therefore ferroelectric, properties) the material of the active layers. By adjusting the orientation of the cavities (one being rotated relative to the other, here by 90°), a different amorphisation and therefore different developed ferroelectric surfaces are thus created.

It will be noted that a single implantation in a given direction (14 or 15) also yields a different amorphisation on the surfaces of cavities 10 and 20. However, it is not appropriate to make four implantations, one with a twist angle of 0°, one with a twist angle of 90°, one with a twist angle of 180°and a last one with a twist angle of 270°: in this case, the surfaces achieved on the two cavities would be identical.

FIGS. 7 to 12 illustrate the different steps of the manufacturing method according to one embodiment of the invention.

As is visible in FIG. 7, the manufacturing method first comprises a step 100 of providing a substrate or support layer 200 on which the array of ferroelectric memory cells will be formed. This support layer 200 is provided with a connection layer 201 for connecting the ferroelectric memory cells to lower metal levels. It will be noted that this support layer 200 may include components that are already present, for example selection transistors on a first level.

The manufacturing method and then continues to step 101 (FIG. 8), during which two cavities 202 and 203 (in which two ferroelectric memory cells 100 will be formed) are formed. This step 101 is implemented by anisotropic etching in order to form the bottom walls 204, 206 and the side walls 205, 207 of the respective cavities 202 and 203. This involves, for example, dry chemical etching.

As described previously, the side wall of each cavity is performed so as to form a non-zero tilt angle relative to the normal to the bottom wall.

The etching masks are beneficially selected so that the two cavities 202 and 203 have identical geometry but are rotated 90°relative to each other. It will be noted that the invention could also be applied with different masks so as to obtain cavities with different geometries; however, the method according to the invention finds particularly interesting application in producing memory cells likewise with the same geometry and made from the same material. The angle of 90°is given for illustrative purposes only; the invention applies whenever the cavities are rotated by a non-zero angle relative to each other. Further, the bottom walls 204 and 206 of the respective cavities 202 and 203 herein have a rectangular shape with a length l that is different from the width L.

The manufacturing method then continues with step 102 in FIG. 9 of conformally depositing a first conductive layer 208 (respectively 211), a ferroelectric active layer 209 (respectively 212) and a second conductive layer 210 (respectively 213) in the cavity 202 (respectively 203). In this description, by “conformal deposition”, it is meant a deposition implemented in such a way that the layer has a substantially constant thickness at all points. The first conductive layers 208 and 211 will form the bottom electrodes of the memory cells and the second conductive layers will form the top electrodes of the memory cells.

The material of the first conductive layers 208, 211 may be, for example, W, a Ti/TiN bilayer, or TiN. The material of the second conductive layers 210, 213 may be W or TiN.

The active layers 209, 212 are herein layers of ferroelectric material, for example based on hafnium dioxide HfO₂. Hafnium dioxide can be doped with a doping element. Here, the doping element used is silicon Si.

Still alternatively, the ferroelectric material layer may comprise an alloy of the form HfₓZr₁₋ₓO₂, where 0<x<1. For example, it is possible to use a ternary alloy such as Hf_{0.5}Zr_{0.5}O₂ as the ferroelectric material.

In some cases, it may be necessary to subsequently make heat treatment on the stack of three layers so that the active layer crystallises into a phase that gives it ferroelectric properties, for example orthorhombic or tetragonal.

And then, the manufacturing method continues to step 103 (FIG. 10), during which a first ion implantation 214 is performed in a manner similar to the first ion implantation described with reference to FIG. 6. The first ion implantation 214 is performed with a twist angle equal to 0 and a tilt angle that is not zero (but which may be zero). It will be noted that the tilt angle is in an embodiment between 10° and 40° so that it is sufficient for the ion beam to reach the side walls but not too high for the beam to reach the bottom wall.

Atoms selected for implantation are in an embodiment heavy species, for example Ge, As or Sb, although lighter species may also be used within the scope of the invention, for example B. The objective being to amorphise the implanted zones of the active layers 209 and 212, it is appropriate to select acceleration voltages and implantation doses adapted to pass through the second conductive layer to reach the active layer. It will be seen in the second embodiment that direct implantation into the active layer is also possible within the scope of the invention.

In an embodiment, the implantation dose is between 1.10¹⁴ cm⁻² and 1.10¹⁷ cm⁻², for example in the order of 1.10¹⁵ cm⁻². The implantation dose will be higher as the implanted species are lighter.

In an embodiment, the acceleration voltage will be between 0.2 kV and 10 kV, for example in the order of 1 kV. The acceleration voltage will be higher as the implanted species are heavier.

The manufacturing method continues in step 104 (FIG. 11), during which a second ion implantation 215 is performed, identical to the second ion implantation described with reference to FIG. 6. The second ion implantation 215 is performed with a twist angle equal to 180° and a tilt angle that is herein not zero and is identical to that of the first implantation (but may be zero). Atoms selected for implantation, dose and acceleration voltage for this second implantation are in an embodiment identical to those of the first implantation 214.

As described with reference to FIG. 6, this results in different surfaces with ferroelectric properties for each of the active layers 209 and 212 with identical cavity geometry and materials.

The method according to the first embodiment of the invention then continues with step 105 (FIG. 12) of filling each of the cavities with a metallic material 216, for example W, followed by a CMP (Chemical Mechanical Polishing) step.

At the end of the manufacturing method according to this first embodiment, an array 217 is obtained including at least two memory cells 218 and 219 (it being understood that the invention is not limited to two, as the array may include more than two devices), herein ferroelectric FeRAM devices, comprising:
at least a first and a second cavity 202 and 203 formed in a support layer 200, each of the first and second cavities:
   having the same geometry and same dimensions;
   comprising a side wall and a bottom wall, said bottom wall having a plurality of sides, at least two sides having different lengths;
   a first conductive layer 208, 211 forming a bottom electrode;
   an active layer 209, 212, herein ferroelectric;
   a second conductive layer 210, 213 forming a top electrode.

The first and second cavities are arranged such that the second cavity is rotated (herein by 90°) relative to the first cavity along an axis normal to the support layer 200. The active layers each have a different implanted surface: in the case of ferroelectric layers, the layers will have a different part of their amorphised surface, thereby losing their ferroelectric properties.

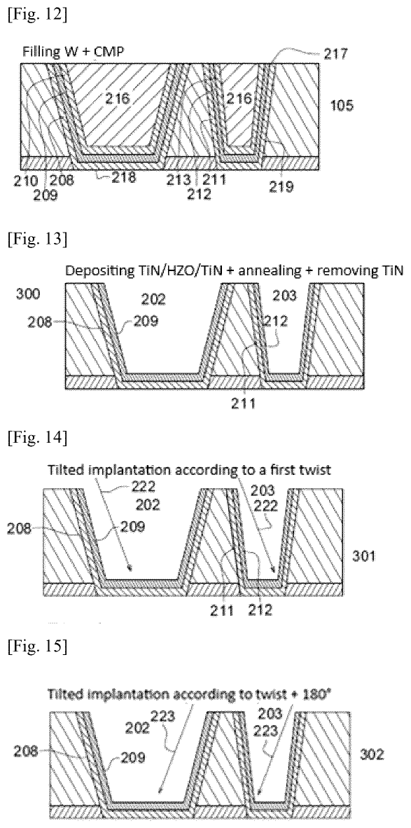

FIGS. 13 to 16 illustrate the different steps of the manufacturing method according to one embodiment of the invention.

The first three steps of the method according to this second embodiment are not illustrated and are identical to steps 100, 101 and 102 in FIGS. 7 to 9.

The method then continues with step 300 illustrated in FIG. 13, during which the second conductive layers 210 and 213 are removed, for example by etching. It will be noted that the presence of the second conductive layer may be important during a possible annealing imparting the ferroelectric properties (and ad hoc crystallisation) of the active layer 209, 212, which is why it is deposited and then removed.

The method then includes a first step 301 of implantation 222 (FIG. 14) similar to step 103 in FIG. 10, the only difference being that the first implantation 222 is performed directly in the active layer 209, 212, allowing more effective control of the implantation in the active layer without passing through the second conductive layer 210, 213 as in the case of FIG. 10.

The method continues with a second step 302 of implantation 223 (FIG. 15) similar to step 104 in FIG. 11, the only difference being that the second implantation 223 is performed directly in the active layer 209, 212.

The method then includes depositing a new conductive layer 220 (aiming to replace the layer 210 that has been removed) on the active layer 209 in cavity 202 and a new conductive layer 221 on the active layer 212 in cavity 203; the conductive layers 220 and 221 act respectively as the top electrode of the memory cells of the array.

The method then continues with a step of filling each of the cavities with a metallic material 216, for example W, followed by a chemical mechanical polishing (CMP) step, as for FIG. 12.

At the end of this step, an array 217 similar to that of FIG. 12 is obtained.

Until now, the bottom wall has been described as having a substantially rectangular shape. The invention is not limited to such a shape and can be applied to more complex shapes to allow working in several directions.

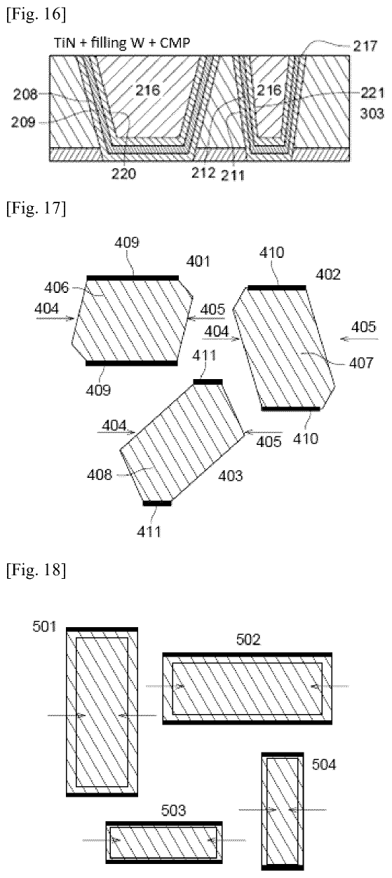

Thus, FIG. 17 illustrates the case of a top view of 3 bottom walls 401, 402 and 403 of the same geometry and simply rotated relative to each other by a non-zero angle. FIG. 17 likewise shows arrows illustrating the two configurations 404 and 405 of the same type as those described with reference to FIG. 6.

It will be noted that it is thus possible, starting from a same complex geometry, to amorphise different surfaces of the three parts by rotating them relative to each other. As previously, the shape of each of the bottom walls has at least two sides with different lengths. Beneficially, the bottom wall has a shape with an even number of sides formed by a plurality of pairs of sides of the same length, at least two pairs of sides having different lengths. Beneficially, the sides of a same pair are parallel to each other. In the case of a rectangle (FIG. 6), there are two pairs of sides, and in the case of FIG. 17, there are 6 sides formed by 3 pairs of sides. Hatched zones 406, 407 and 408 represent the amorphised zones, while the solid lines 409, 410 and 411 represent the zones that remained ferroelectric after implantation. As can be seen, the surfaces that remained ferroelectric are different for the three memory cells associated with the respective bottom walls 401, 402 and 403.

It will be noted that it is also possible to implement the method according to the invention by combining it with a variation in size or geometry on the cavities made. In other words, as illustrated in FIG. 18, the method can be implemented on two first cavities 501 and 502 that are identical in terms of geometry and materials (as in FIGS. 6 to 16) and on two second cavities 503 and 504 that are also identical in terms of geometry and materials but different from the first two cavities, for example in terms of dimensions. Herein it can be seen that the rectangular bottom walls of the first cavities are wider and longer than the rectangular bottom walls of the second cavities.

Although the invention has been described more specifically in the case of ferroelectric FeRAM type memory cells, the invention could also be applied to other types of memory cells, for example metal oxide resistive memories, called OxRAM, for which the aim is to modify, by implantation, the active layers of at least two cells, with the surfaces of the active layers being implanted on different areas. Implantation can, for example, improve or degrade performance (forming voltage, endurance, variability) of an OxRAM memory; thus, by differently implanting two respective active layers of two OxRAMs, it is possible to obtain two OxRAM memories with different properties. Another possible application is the co-integration of FeRAM memories with OxRAM memories: one way to achieve this is to use a same active layer material for both OxRAM and FeRAM, by performing a different doping according to the type of memory (FeRAM or OxRAM): thus, by virtue of the invention, it is possible to implant and therefore dope two memory cells different by acting on the effective area of the active layer implanted and thus obtain either a FeRAM memory or an OxRAM memory according to the type of implantation.

Expressions such as “comprise”, “include”, “incorporate”, “contain”, “is” and “have” are to be construed in a non-exclusive manner when interpreting the description and its associated claims, namely construed to allow for other items or components which are not explicitly defined also to be present. Reference to the singular is also to be construed in be a reference to the plural and vice versa.

The articles “a” and “an” may be employed in connection with various elements and components, processes or structures described herein. This is merely for convenience and to give a general sense of the compositions, processes or structures. Such a description includes “one or at least one” of the elements or components. Moreover, as used herein, the singular articles also include a description of a plurality of elements or components, unless it is apparent from a specific context that the plural is excluded.

As used herein in the specification and in the claims, the phrase “at least one”, in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified.

A person skilled in the art will readily appreciate that various features, elements, parameters disclosed in the description may be modified and that various embodiments disclosed may be combined without departing from the scope of the invention. For example, various aspects of the present disclosure may be used alone, in combination, or in a variety of arrangements not specifically described in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Having described above several aspects of at least one embodiment, it is to be appreciated various alterations, modifications, and improvements will readily occur to those skilled in the art. Such alterations, modifications, and improvements are intended to be aspects of this disclosure. Accordingly, the foregoing description and drawings are by way of example only.

What is claimed is

1. A method for manufacturing an array of memory cells including at least two memory cells, the method comprising:
providing a substrate;
forming at least a first and a second cavity in the substrate;
the first and second cavities being oriented such that the second cavity undergoes rotation by a non-zero angle about an axis normal to the substrate relative to said first cavity, said method including the following steps implemented in each of the cavities:
depositing a first conductive layer;
depositing an active layer;
depositing a second conductive layer;
the method further including at least one ion implantation step such that areas of the active layers exposed to implantation in the first and second cavities, which are oriented differently, are different.

2. The method according to claim 1, wherein the first and second conductive layers are metallic layers.

3. The method according to claim 1, wherein each of said first and second cavities:
has the same geometry and same dimensions;
comprises a side wall and a bottom wall, said bottom wall having a plurality of sides, at least two sides having different lengths.

4. The method according to claim 3, wherein the bottom wall has a shape with an even number of sides formed by a plurality of opposite sides of the same length, at least two pairs of sides having different lengths.

5. The method according to claim 1, wherein the memory cells are at least partly FeRAM ferroelectric memories, the active layer being a ferroelectric or antiferroelectric layer.

6. The method according to claim 1, wherein the memory cells are at least partly OxRAM memories, the active layer being a metal oxide-based layer.

7. The method according to claim 6, wherein the array of memory cells includes at least one FeRAM memory and at least one OxRAM memory.

8. The method according to claim 1, wherein the material of the active layer is hafnium dioxide HfO₂ doped with Si or an alloy HfₓZr₁₋ₓO₂, with 0<x<1, or AlScN.

9. The method according to claim 1, wherein the implantation dose is between 1.10¹⁴ cm⁻² and 1.10¹⁷ cm⁻² and the implantation acceleration voltage is between 0.2 kV and 10 kV.

10. The method according to claim 1, wherein the implantation is performed using one of the following atoms: Ge, As, Sb, In, P, Si, Ga, C or B.

11. The method according to claim 1, comprising two ion implantation steps in two different directions to target different surfaces of each of the active layers.

12. The method according to claim 11, wherein a first implantation is performed with a rotation angle of the substrate in the plane of the substrate of 0°and a second implantation is performed with a rotation angle of the substrate in the plane of the substrate of 180°.

13. The method according to claim 1, wherein the implantation is performed with a tilt angle between the ion beam and the normal to the surface of the substrate strictly less than 90°.

14. The method according to claim 13, wherein the tilt angle is between 10 and 40°.

15. The method according to claim 1, wherein the first and second cavities are oriented such that the second cavity undergoes a rotation by an angle of 90° about an axis of direction normal to the substrate relative to said first cavity.

16. The method according to claim 1, wherein the implantation is performed through the second conductive layer.

17. The method according to claim 1, further comprising:
removing the second conductive layer, the implantation being directly performed in the active layer after removing the second conductive layer;
depositing a new conductive layer onto the active layer after implantation.

18. An array including at least two memory cells comprising:
at least a first and a second cavity in a substrate, the first and second cavities being oriented such that the second cavity has a rotation of a non-zero angle about an axis normal to the substrate relative to said first cavity, each of the first and second cavities including:
a first conductive layer forming a bottom electrode;
an active layer;
a second conductive layer forming a top electrode;
the active layers of the first and second cavities having different implanted areas.
